(19) United States
(12) Patent Application Publication
(10) Pub. No.: US 2014/0154424 A1
(43) Pub. Date: Jun. 5, 2014

(54) ROLL-TO-ROLL SPUTTERING METHOD

(71) Applicant: Samsung Corning Precision Materials Co., Ltd., Gyeongsangbuk-do (KR)

(72) Inventors: Jung Hong Oh, ChungCheongNam-Do (KR); Jin Soo An, ChungCheongNam-Do (KR); Chang Moog Rim, ChungCheongNam-Do (KR); Gi Mo Yang, Chungcheongnam-do (KR); Sang Yoon Oh, ChungCheongNam-Do (KR)

(73) Assignee: Samsung Corning Precision Materials Co., Ltd., Gyeongsangbuk-do (KR)

(21) Appl. No.: 14/093,777

(22) Filed: Dec. 2, 2013

(30) Foreign Application Priority Data
Dec. 3, 2012 (KR) 10-2012-0138963

(51) Int. Cl. C23C 14/50

(52) U.S. Cl. CPC C23C 14/505
USPC 427/523

(57) ABSTRACT

A roll-to-roll sputtering method transports a flexible substrate wound on an unwinder roll to a depositing part, forms a deposited film on the flexible substrate, and winds the flexible substrate on a winder roll. The depositing part includes a first depositing part. The first depositing part includes a first sputtering part which deposits a first target material on one surface of the flexible substrate and a heater which is disposed at a side of the other surface of the flexible substrate to heat the flexible substrate.

### CROSS REFERENCE TO RELATED APPLICATION

The present application claims priority from Korean Patent Application Number 10-2012-0138963 filed on Dec. 3, 2012, the entire contents of which are incorporated herein for all purposes by this reference.

### BACKGROUND OF THE INVENTION

1. Field of the Invention

The present invention relates to a roll-to-roll sputtering method, and more particularly, to a roll-to-roll sputtering method that forms a deposited film on a flexible substrate by sputtering deposition.

2. Description of Related Art

In general, flexible substrates which surround liquid crystal in a liquid crystal display of a flexible display, an organic electroluminescent (EL) display, electrophoretic ink (E-ink) or the like are implemented as a polymer thin film that is highly flexible.

The polymer thin film is coated with a transparent conductive film, a functional coating layer or the like made of indium tin oxide (ITO), ZnO, SnO₂, In₂O₂, Nb₂O₅, SiOₓ or the like by a roll-to-roll sputtering method.

FIG. 1 is a schematic configuration view showing a roll-to-roll sputtering apparatus of the related art.

Referring to FIG. 1, the roll-to-roll sputtering apparatus of the related art includes an unwinder roll 10, a winder roll 20, a plurality of guide rolls 10a and 20a, a cooling drum 30 and a sputter 40.

The unwinder roll 10 and the winder roll 20 unwind and wind a polymer thin film through cooperative rotation therebetween. The plurality of guide rolls 10a and 20a are arranged at certain distances in order to facilitate control over tension when the polymer thin film is being rolled. The polymer thin film is continuously transported onto the cooling drum 30 due to mechanical cooperation of the unwinder roll 10, the winder roll 20, and the plurality of guide rolls 10a and 20a. In addition, the sputter 40 forms a deposited film on the polymer thin film that is transported onto the cooling drum 30.

The cooling drum 30 prevents the polymer thin film from melting or deforming due to heat during sputtering. Since the polymer thin film has poor heat resistance, the cooling drum 30 is necessarily required in order to form the deposited film on the polymer thin film.

Technology about the roll-to-roll sputtering apparatus is disclosed in Korean Patent Publication No. 10-2011-0012182 (Feb. 9, 2011).

In response to recent development of displays and the relevant information technology (IT) industry, a variety of devices which use laminated glass in place of the polymer thin film as a flexible substrate is being developed. Accordingly, roll-type flexible glass products having a thickness of 100 μm or less are being developed and commercially distributed. Glass can be advantageously coated with a variety of coating materials under various thermal conditions, since it has strong heat resistance and superior moisture permeability compared to polymer thin films.

However, when flexible glass is coated with a coating material using the roll-to-roll sputtering apparatus of the related art including the cooling drum, the advantages of the flexible glass having superior heat resistance are not sufficiently put to practical use, which is problematic.

In particular, indium tin oxide (ITO) that is attracting interest has superior quality due to improved crystallinity when it is deposited at a high temperature of 150° C. or higher. However, the hot coating process is not applicable when the roll-to-roll sputtering apparatus of the related art is used. Accordingly, a method of coating the flexible glass with ITO at low temperature after depositing a seed layer made of SiOₓ or the like on the flexible glass can be used. However, this method has drawbacks in that an additional cathode for forming the seed layer is necessary and the resistivity and transmittance characteristics of resultant ITO are inferior to those of ITO that is crystallized at high temperature.

The information disclosed in the Background of the Invention section is provided only for better understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a roll-to-roll sputtering method that can perform a hot sputtering deposition process.

In an aspect of the present invention, provided is a roll-to-roll sputtering method which transports a flexible substrate wound on an unwinder roll to a depositing part, forms a deposited film on the flexible substrate, and winds the flexible substrate on a winder roll. The depositing part includes a first depositing part. The first depositing part includes: a first sputtering part which deposits a first target material on one surface of the flexible substrate; and a heater which is disposed at a side of the other surface of the flexible substrate to heat the flexible substrate.

According to an embodiment of the present invention, the depositing part may further include a second depositing part. The second depositing part includes: a second sputtering part which deposits a second target material on the one surface of the flexible substrate; and a cooling drum which contacts and cools down the flexible substrate.

The cooling drum may have a flow path therein. Cooling water flows along the flow path in order to maintain the flexible substrate at a predetermined temperature.

The second sputtering part may include a plurality of sputtering parts.

The first depositing part may include a heat insulation member which blocks transfer of heat generated by the heater to the outside of the first depositing part. The first depositing part may further include cooling means for preventing heat generated by the heater from being transferred to the outside of the first deposition part.

The flexible substrate may include flexible glass.

The heater may crystallize the first target material deposited on the one surface of the flexible substrate.

The first sputtering part may include a plurality of sputtering parts.

According to embodiments of the present invention, it is possible to perform hot sputtering by heating the flexible substrate using the heater.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a schematic configuration view showing a roll-to-roll sputtering apparatus of the related art;

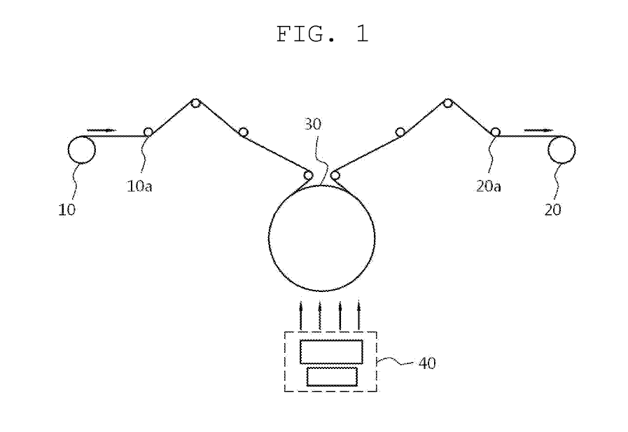

FIG. 2 is a schematic conceptual view showing a roll-to-roll sputtering apparatus according to a first exemplary embodiment of the present invention; and

FIG. 3 is a schematic conceptual view showing a roll-to-roll sputtering apparatus according to a second exemplary embodiment of the present invention.

### DETAILED DESCRIPTION OF THE INVENTION

Reference will now be made in detail to a roll-to-roll sputtering method according to the present invention, embodiments of which are illustrated in the accompanying drawings and described below, so that a person having ordinary skill in the art to which the present invention relates can easily put the present invention into practice.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

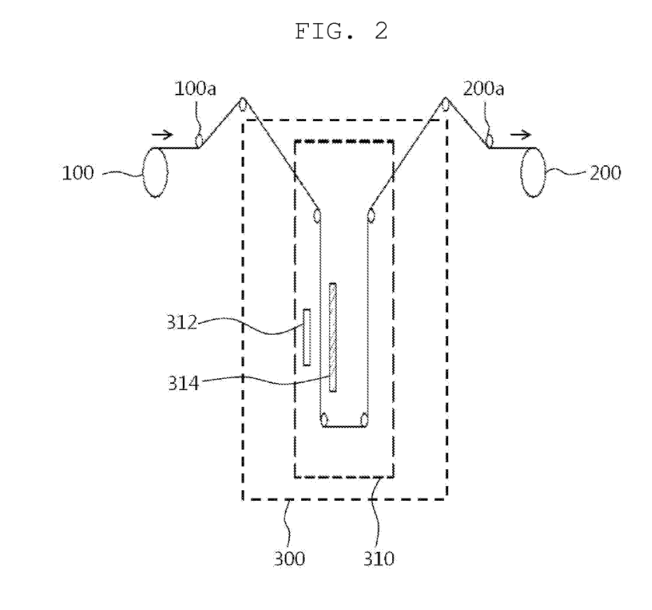

FIG. 2 is a schematic conceptual view showing a roll-to-roll sputtering apparatus according to a first exemplary embodiment of the present invention.

Referring to FIG. 2, the roll-to-roll sputtering apparatus according to this embodiment includes an unwinder roll 100, a depositing part 300 including a first depositing part 310, a winder roll 200, and a plurality of guide rolls 100a and 200a.

The unwinder roll 100 and the winder roll 200 serve to unwind or wind a flexible substrate through cooperative rotation therebetween.

The plurality of guide rolls 100a and 200a are arranged at certain distances in order to facilitate control over tension when the flexible substrate is being rolled. A tension adjustment device and a tension control sensor can be attached to the guide rolls so that the flexible substrate can be rolled under a certain level of tension.

The flexible substrate is continuously transported to the depositing part due to the mechanical cooperation of the unwinder roll 100, the plurality of guide rolls 100a and 200, and the winder roll 200. The flexible substrate can be implemented as flexible glass. It is preferred that the flexible glass has a thickness of 100 μm.

The depositing part 300 is a reaction area in which a film is deposited by sputtering deposition on the flexible substrate which is transported through the mechanical cooperation of the unwinder roll 100, the plurality of guide rolls 100a and 200a, and the winder roll 200. The depositing part 300 includes the first depositing part 310.

The first depositing part 310 includes a first sputtering part 312 and a heater 314.

The first sputtering part 312 includes a first target (not shown) made of a material which is to form the deposited film on the flexible substrate and a cathode (not shown) which is a power source to discharge atoms from the first target. The first sputtering part 312 forms the deposited film by depositing the first target material on one surface of the flexible substrate. It is preferred that the first target be made of a material such as indium tin oxide (ITO), indium zinc oxide (IZO), aluminum zinc oxide (AZO) or the like that is to crystallize due to subsequent heat treatment by the heater 314.

The first sputtering part 312 can include a plurality of sputtering parts. The plurality of sputtering parts can be implemented as targets that are made of the same material or different materials. When the targets are made of the same material, it is possible to deposit a thick film on the flexible substrate at high speed. When the targets are made of different materials, it is possible to coat the flexible substrate with a multilayer structure in which deposited films made of the respective target materials are stacked on each other.

The heater 314 is disposed at the side of the other surface of the flexible substrate to heat the flexible substrate.

Since the heater 314 heats the flexible substrate, it is possible to coat the flexible substrate with a target material that is required to be deposited at high temperature.

It is preferred that the heater 314 crystallize the first target material that is deposited on one surface of the flexible substrate. Some materials such as ITO, IZO and AZO have low specific resistance and high transmittance when they are deposited or heat-treated at high temperature. Accordingly, the roll-to-roll sputtering apparatus according to the present invention can perform hot sputtering deposition by heating the flexible substrate using the heater 314, thereby depositing a high-quality film.

The first depositing part 310 according to the present invention can include a heat insulation member (not shown) which blocks transfer of heat generated by the heater 314 to the outside of the first depositing part 310. In other words, the first depositing part 310 can include the heat insulation member in order to prevent the other parts of the roll-to-roll sputtering apparatus 300 from being influenced by heat from the heater 314. In addition, the first depositing part 310 according to the present invention can further include cooling means (not shown) for preventing heat generated by the heater 314 from being transferred to the outside of the first deposition part 310.

In addition, the first depositing part 310 can include a heat resistant member in order to resist heat generated by the heater 314.

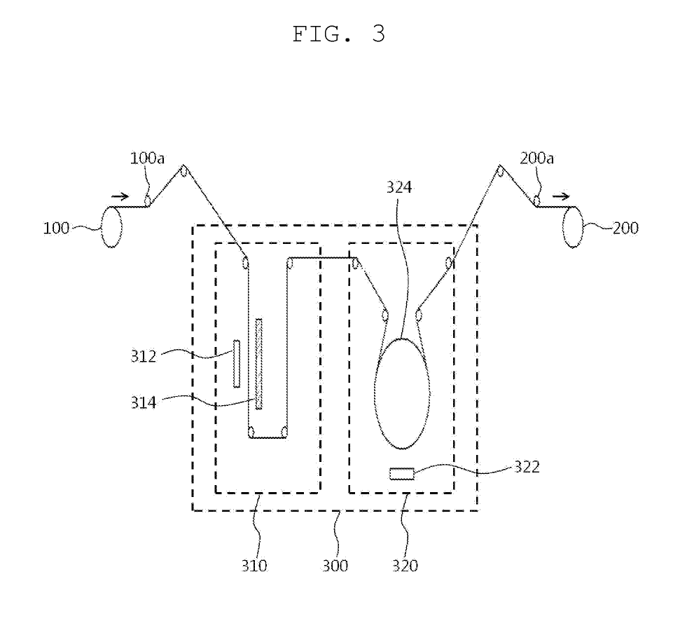

FIG. 3 is a schematic conceptual view showing a roll-to-roll sputtering apparatus according to a second exemplary embodiment of the present invention.

Referring to FIG. 3, the roll-to-roll sputtering apparatus according to the present invention includes an unwinder roll 100, a depositing part 300 which includes a first depositing part 310 and a second depositing part 320, an unwinder roll 200, and a plurality of guide rolls 100a and 200a.

In the following, the same reference numerals are used to designate some features that are identical to those of the above-described first embodiment of the present invention and descriptions thereof will be omitted.

The depositing part 300 is a reaction area in which a film is deposited by sputtering deposition on the flexible substrate which is transported through the mechanical cooperation of the unwinder roll 100, the plurality of guide rolls 100a and 200a, and the winder roll 200. The depositing part 300 includes the first depositing part 310 and the second depositing part 320 which is disposed upstream or downstream of the first depositing part 310. Thus, the depositing part 300 is divided into two reaction areas, and preferably, the first depositing part 310 and the second depositing part 320 are separated from each other so that a reaction in one area does not influence a reaction in the other area.

Since the depositing part 300 is divided into the first depositing part 310 and the second depositing part 320, a high-temperature deposition process and a low-temperature deposition process can be concurrently performed. In addition, when the first depositing part 310 is turned off, it is possible to perform deposition using a polymer thin film that has poor heat resistance as a flexible substrate.

The second depositing part 320 includes a second sputtering part 322 and a cooling drum 324.

The second sputtering part 322 includes a second target (not shown) made of a material which is to form the deposited film and a cathode (not shown) which is a power source to discharge atoms from the second target. The second sputtering part 322 forms the deposited film by depositing the second target material on one surface of the flexible substrate. The second target can be made of a variety of materials, such as SiO₂ or Nb₂O₅.

The second sputtering part 322 can include a plurality of sputtering parts. The plurality of second sputtering parts 322 can be implemented as targets that are made of the same material or different materials. When the targets are made of the same material, it is possible to deposit a thick film on the flexible substrate at high speed. When the targets are made of different materials, it is possible to coat the flexible substrate with a multilayer structure in which deposited films made of the respective target materials are stacked on each other.

The cooling drum 324 contacts and cools down the flexible substrate.

The surface of the cooling drum 324 can be polished to be smooth in order to prevent the flexible substrate from being scratched due to contact with the cooling drum. In addition, it is possible to control the speed at which the flexible substrate is transported and the speed at which the cooling drum 324 rotates so as to coincide with each other.

In addition, a flow path (not shown) along which cooling water flows can be formed inside the cooling drum 324. The cooling water flows along the flow path (not shown) in order to maintain the flexible substrate at a certain temperature by dispersing or removing heat energy generated during the process of forming the deposited film.

The foregoing descriptions of specific exemplary embodiments of the present invention have been presented with respect to the drawings. They are not intended to be exhaustive or to limit the present invention to the precise forms disclosed, and obviously many modifications and variations are possible for a person having ordinary skill in the art in light of the above teachings.

It is intended therefore that the scope of the present invention not be limited to the foregoing embodiments, but be defined by the Claims appended hereto and their equivalents.

What is claimed is:

1. A roll-to-roll sputtering method which transports a flexible substrate wound on an unwinder roll to a depositing part, forms a deposited film on the flexible substrate, and winds the flexible substrate on a winder roll, wherein the depositing part comprises a first depositing part, the first depositing part comprising:
a first sputtering part which deposits a first target material on one surface of the flexible substrate; and
a heater which is disposed at a side of the other surface of the flexible substrate to heat the flexible substrate.

2. The roll-to-roll sputtering method of claim 1, wherein the depositing part further comprises a second depositing part, the second depositing part comprising:
a second sputtering part which deposits a second target material on the one surface of the flexible substrate; and
a cooling drum which contacts and cools down the flexible substrate.

3. The roll-to-roll sputtering method of claim 2, wherein the cooling drum has a flow path therein, wherein cooling water flows along the flow path in order to maintain the flexible substrate at a predetermined temperature.

4. The roll-to-roll sputtering method of claim 2, wherein the second sputtering part comprises a plurality of sputtering parts.

5. The roll-to-roll sputtering method of claim 2, wherein the first target material and the second target material are a same material or different materials.

6. The roll-to-roll sputtering method of claim 2, wherein the first target material comprises ITO, and the second target material comprises Nb₂O₅ or SiO₂.

7. The roll-to-roll sputtering method of claim 2, wherein the flexible substrate comprises an organic film, and only the second target material is deposited with the second depositing part on and the first depositing part off.

8. The roll-to-roll sputtering method of claim 1, wherein the first depositing part comprises a heat insulation member which blocks transfer of heat generated by the heater to an outside of the first depositing part.

9. The roll-to-roll sputtering method of claim 8, wherein the first depositing part further comprises cooling means for preventing heat generated by the heater from being transferred to an outside of the first deposition part.

10. The roll-to-roll sputtering method of claim 1, wherein the flexible substrate comprises flexible glass.

11. The roll-to-roll sputtering method of claim 1, wherein the heater crystallizes the first target material deposited on the one surface of the flexible substrate.

12. The roll-to-roll sputtering method of claim 1, wherein the first sputtering part comprises a plurality of sputtering parts.
